(19) United States
(12) Patent Application Publication
(10) Pub. No.: US 2020/0287150 A1
(43) Pub. Date: Sep. 10, 2020

(54) OLED STRUCTURE AND METHOD OF MAKING THEREOF

(71) Applicants: Interface Technology (ChengDu) Co., Ltd., Chengdu City (CN); Interface Optoelectronics (ShenZhen) Co., Ltd., Shenzhen City (CN); General Interface Solution Limited, Miaoli County (CN)

(72) Inventor: Chin-Feng CHUNG, Miaoli County (TW)

(21) Appl. No.: 16/364,982

(22) Filed: Mar. 26, 2019

(30) Foreign Application Priority Data
Mar. 5, 2019 (CN) 201910163330.5

(51) Int. Cl. H01L 51/50; H01L 51/52; H01L 51/56; H01L 51/00; H01L 27/32

(52) U.S. Cl. CPC H01L 51/504; H01L 51/5278; H01L 51/5056; H01L 51/5072; H01L 27/3211; H01L 51/56; H01L 51/001; H01L 51/0011; H01L 51/5088

(57) ABSTRACT

An OLED structure comprises a node electrode, a hole injection layer, a first hole transporting layer, and a blue emitting layer. The OLED structure further comprises a second hole transporting layer, a green emitting layer disposed on the second hole transporting layer; and a red emitting layer disposed on a portion of the green emitting layer. The OLED structure also comprises an electron transport layer and a cathode. A method of manufacturing the OLED structure is also provided.

### BACKGROUND OF THE INVENTION

### Field of the Invention

The present invention relates to the field of organic light-emitting diodes. More particularly, the present invention discloses a structure and a method for preparing a full-color organic light-emitting diode through a material design layer structure.

### Description of the Prior Art

The conventional Organic Light-Emitting Diode (OLED) has many pixel arrangement modes. A side-by-side process is commonly used to achieve the effect of an ultra-high resolution full color display.

The active matrix OLED (Active-matrix organic light-emitting diode, AMOLED) has the advantages of self-emitting, wide viewing angle, high contrast, and fast response.

Standard parallel AMOLEDs usually use precision metal masks (Fine metal mask, FMM) to deposit the organic light emitting material on a substrate. A similar deposited pixel arrangement is illustrated in FIG. 1A and FIG. 1B. Due to the limitation of luminous efficiency of the OLED material, the blue organic light-emitting material has a high loss rate. As a result, it is often formed over a large area. Therefore, the R/G and B light-emitting areas cannot share the same mask and it is necessary to design the FMM with different openings.

However, to obtain a high technology FMM and increase the substrate alignment accuracy, the resultant mask is easily deformed due to gravity and thermal expansion. Also, using the conventional method the material utilization is low and the opening processing affects the light emitting element resolution. All of these issues contribute to increase the cost of production due to the process being expensive and difficult.

### SUMMARY OF THE INVENTION

In view of the above disadvantages, and in order to overcome the above drawbacks of the prior art, the present invention provides an R/G/B output from the light emitting stack structure of an organic light emitting material wherein the structure of the invention has a negative potential difference and allows current tunneling through the intermediate structure in series.

The design of the combined and shared layers is used to achieve high-precision illuminating element patterning.

The OLED stacked structure of the present invention comprises: a first common layer substrate, the substrate comprising an anode, a hole injection layer (hole injection layer, HIL), a first hole transport layer (hole transporting layer, HTL), and a blue organic light-emitting layer (emmiting layer, EML); a second hole transport layer stacked on top of the blue organic light emitting layer portion; a green organic light emitting layer stacked on the second hole transport layer; a red organic light emitting layer stacked on top of the green organic light emitting layer portion; a second common layer comprising an electron transporting layer (electron transport layer, ETL), and a cathode.

To enhance current injection effects, the stacked structure of the present invention may be disposed between the green EML and the blue EML with an addition of a charge generating layer (charge generation layer, CGL), which is flanked by an N-type doped layer and a P-type doped layer.

The present invention also has the advantage of the structure utilizing the high energy transfer blue EML as a common layer in order to reduce costs by using the FMM during stacking, reducing the number of alignment process steps, and improving the precision and accuracy.

In addition, unlike the conventional RGB side by side pattern arrangement (as shown in FIG. 1A and FIG. 1B) in which the evaporation of the EML requires three FMMs to align the substrate, the present invention only requires two FMMs.

Furthermore, the structure of the present invention can reduce the distance between RGB organic materials and improve the resolution.

### BRIEF DESCRIPTION OF THE DRAWINGS

FIG. 1A is a drawing illustrating a parallel (side-by-side) OLED structure of the prior art;

FIG. 1B is a drawing illustrating a parallel (side-by-side) OLED structure of the prior art;

FIG. 2 is a drawing illustrating a stacked structure of an OLED according to an embodiment of the present invention; and

FIG. 3 is a drawing illustrating a stacked structure of an OLED according to an embodiment of the present invention.

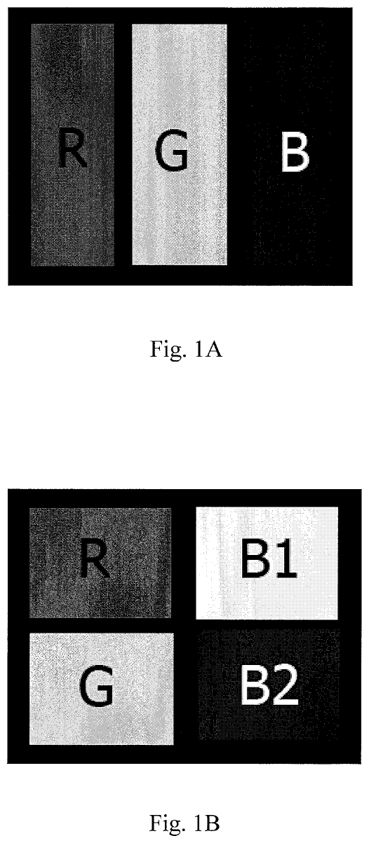

### DESCRIPTION OF THE PREFERRED EMBODIMENTS

The following embodiments are merely exemplary in nature and are not intended to limit the invention or the application of the invention. Furthermore, there is no intention to be bound by any explicit or implied theory as set forth in the sections of this disclosure. It should also be noted that the illustrations are illustrative and may not be drawn to scale. It will be appreciated by those skilled in the art that the described embodiments may be modified in various different forms without departing from the spirit and scope of the invention.

In an embodiment, the organic light emitting layer of the OLED is formed through a mask deposition method having the same pattern of the organic light emitting layer disposed on the subject material FMNI, wherein deposition through the mask and the material system deposited forms the organic light-emitting layer of the desired pattern on the target material.

The method of performing the mask deposition is as follows. When forming the green light emitting layer and the red light emitting layer, a first FMNI and a second FMNI are used, so the mask process is performed twice.

For example, the green light emitting layer is deposited using a first FMM and the red light emitting layer is deposited using a second emission layer pattern FMM thereby completing the respective pixels.

In an embodiment of the present invention the OLED is an AMOLED.

The method of the organic light emitting diode stack structure of the present invention comprises the steps of: using a carrier using a rigid plate to form the process definition area of a pattern through photolithography; using a common mask to form a large area deposition common layer, comprising a hole injection layer/a first hole transport layer/a blue light emitting layer (HIL/HTL/Blue EML) material as a common layer stack; optically aligning the FMM pattern to the anode pixel area (non-blue subpixel opening area) using a magnet to fix the metal mask in order to prevent the process from rotating; fabricating an N-type doped layer/a charge generating layer/a P-type doped layer/a second hole transport layer/a green light-emitting layer (N*/CGL/P*/HTL/Green EML) stack through the first FMM structure; transferring the FMM to a vacuum machine, where the metal mask pattern can be an aligned anode pixel region of the substrate (Red subpixel opening region), making a Red EML; and depositing the ETL/cathode material as a common layer by a common mask evaporation method. In an embodiment the second track is smaller than the opening of the FMM of the openings of the first FMM.

In an embodiment of the present invention the N*/CGL/P*/HTL/Green EML stack structure is stacked on a common layer comprising HIL/HTL/blue EML materials.

In an embodiment of the present invention the OLED structure on the substrate comprises: a first common layer substrate 11, the substrate 11 comprising an anode, a hole injection layer 12 positioned on the anode substrate 11, a first hole transport layer 13 located above the hole injection layer 12, and a blue light emitting layer 14 located on the hole transport layer 13; a first charge generating structure 2 comprising a first N-type bottom doped layer 21, a first charge generation layer 22, and a first P-type doped layer 23; a second hole transport layer 3; a green light-emitting layer 4 stacked on the second hole transport layer 3; a red light emitting layer 5 over a portion of the green light-emitting layer 4; a second common layer 6 disposed on top of the red light emitting layer 5, and an electron transporting layer comprising an anode 61 and a cathode 62. The first charge-generating structure 2, the second hole transport layer 3, the green light emitting layer 4 and the blue light emitting layer 14 are stacked over portions of the substrate 11.

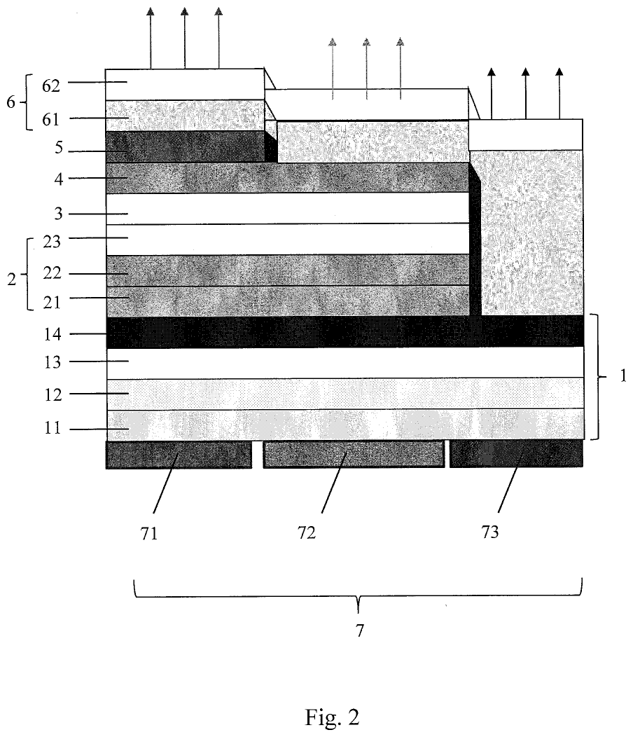

As can be seen in FIG. 2, the entire OLED pixel region 7 is divided into three sub-pixel regions. The red luminescent layer will emit light in the red sub-pixel region 71, the green luminescent layer will emit light in the green sub-pixel region 72, and the blue luminescent layer will emit light in the blue sub-pixel region 73.

Green light is the most recognizable spectrum for human eyes and is the EML with the highest conversion efficiency among mature organic luminescent materials. Therefore, the structure of FIG. 2 can be used to reduce the green layer (reduce the conversion efficiency of green light). Most of the holes/electrons are combined adjacent to the red light-emitting layer so that the luminous efficiency of the red light EML can be increased.

The laminated R/G layer is directly transmitted through the material so as to be stacked in proximity with the fluorescence (phosphorescence) system and can produce a feeling similar to the yellow light emitting layer. In another embodiment the stacking comprises a combination of alternative constructions.

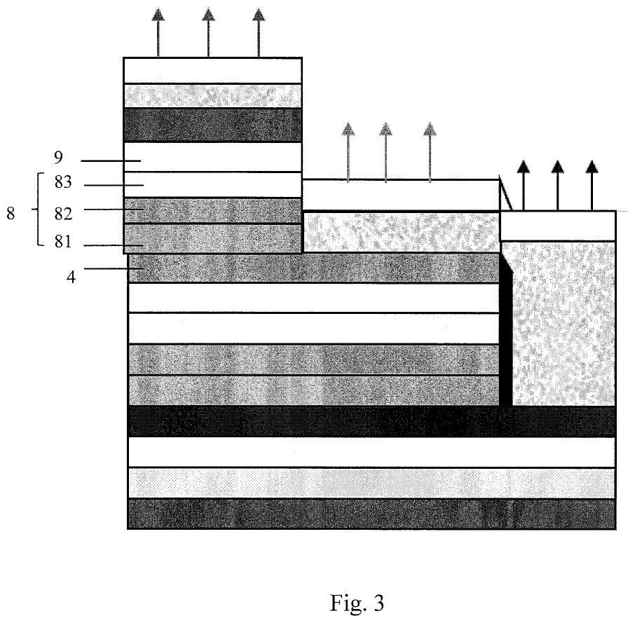

Referring to FIG. 3, a second channel using a second FMM adds another charge generation structure 8 between the R/G layers. The second charge-generating structure 8 comprises a second N-type doped layer 81, a second charge generation layer 82, and a second P-type doped layer 83. The second charge-generating structure 8 is disposed adjacent to the third hole transport layer 9. A single red or green spectrum dominated mechanism is achieved through material process design of the present invention. This structure is different from the traditional yellow light-emitting layer which must pass light through the color filter to purify the color source. Another difference between the two is the inclusion of the red and green layers.

The design of the present invention provides the individual lights of R, and B in order to improve in color purity.

Also, the specifications of display technology achieve improved progress of the OLED organic material without using filters. This is an advantage that the yellow OLED cannot achieved.

It is to be understood that the above described embodiments of the present invention are only examples, and are not intended to limit the scope, applicability, or configuration of the invention in any manner. Various changes in the function and arrangement of the elements can be made without departing from the scope of the invention and the legal equivalents thereof.

1. An organic light emitting diode stack structure comprising:
a first common layer substrate comprising an anode and a hole injection layer;
a first hole transport layer above the hole injection layer;
a blue light emitting layer located above the first hole transport layer;
a second hole transport layer stacked on a portion of the blue light emitting layer;
a green light emitting layer stacked on the second hole transport layer;
a red light emitting layer stacked on top of the green light emitting layer;
a second common layer substrate disposed on the red light emitting layer, the second common layer substrate comprising an electron transport layer and a cathode formed on the electron transport layer;
a first charge generating structure disposed between the blue light emitting layer and the green light emitting layer, the first charge generating structure comprising:
a first N-type doped layer disposed over the blue light emitting layer;
a first P-type doped layer disposed below the first green light emitting layer; and
a charge generation layer disposed between the first doped N-type layer and the first P-type doped layer.

2. The organic light emitting diode stack structure of claim 1,
wherein the organic light emitting diode stack structure is divided into a red sub-pixel region, a blue sub-pixel region and a green sub-pixel region.

3. The organic light emitting diode stack structure of claim 2, further comprising:
a second charge generating structure disposed between the green light emitting layer and the red light emitting layer, the second charge generating structure comprising:
a second N-type doped layer disposed above the green-light emission layer;
a second P-type doped layer disposed below the red light emitting layer; and
a second charge generation layer disposed between the second N-type doped layer and the second P-type doped layer.

4. The organic light emitting diode stack structure of claim 1, wherein the organic light emitting diode stack structure is an active matrix organic light emitting diode stack structure.

5. A method for preparing an organic light emitting diode stack structure comprising:
using photolithography to define a process area pattern on a first common layer;
performing vaporization on the first common layer using a common mask, the first common layer comprising a hole injection layer, a first hole transport layer, and a blue light emitting layer;
bonding a metal to a first mask to form a first metal mask;
utilizing the first metal mask to form a first N-type doped layer, a first charge generation layer, a first P-type doped layer, a second hole transport layer, and a green light emitting layer stack structure;
removing the first metal mask;
utilizing a second metal mask to form a red luminescent layer;
removing the second metal mask; and
evaporating an electron transport layer and a cathode material.

6. The method for preparing an organic light emitting diode stack structure of claim 5, wherein a second metal mask opening is smaller than a first metal mask opening.

7. The method for preparing an organic light emitting diode stack structure of claim 5, wherein vapor deposition is performed in a vacuum environment.

8. The method for preparing an organic light emitting diode stack structure of claim 5, further comprising:
forming a second N-type doped layer, a second charge generation layer, a second P-type doped layer, and a third hole transport layer.
